(19) United States
(12) Patent Application Publication
(10) Pub. No.: US 2025/0239505 A1
(43) Pub. Date: Jul. 24, 2025

(54) METHOD FOR MANUFACTURING ELECTRONIC COMPONENTS

(71) Applicant: STMicroelectronics International N.V., Geneva (CH)

(72) Inventor: Ludovic FALLOURD, Louans (FR)

(21) Appl. No.: 19/019,953

(22) Filed: Jan. 14, 2025

(30) Foreign Application Priority Data
Jan. 19, 2024 (FR) FR2400539

(51) Int. Cl. H01L 23/495; H01L 21/56; H01L 21/60; H01L 23/31

(52) U.S. Cl. CPC H01L 23/49517; H01L 21/561; H01L 21/60; H01L 23/3107; H01L 2021/60007

(57) ABSTRACT

The present description provides a method for manufacturing electronic components. with wettable flanks. In an example, the method of manufacturing electronic components is for electronic components with wettable flanks from a substrate. A first face of the substrate is covered by connection terminals. The substrate is in which chips are formed. The method includes soldering a metal grid comprising connection pads interconnected by bars to the connection terminals; forming an insulating resin layer on the substrate, wherein the insulating resin layer surrounds the connection pads; separating the chips from one another; and obtaining electronic components with wettable flanks, wherein a lateral part of the connection pads and a part of the insulating resin layer form the wettable flanks of the electronic components.

### CROSS REFERENCE TO RELATED APPLICATIONS

This application claims the priority benefit of French patent application number 2400539, filed on Jan. 19, 2024, entitled “Procédé de fabrication de composants électroniques”, which is hereby incorporated by reference to the maximum extent allowable by law.

### TECHNICAL FIELD

The present description relates to the manufacture of electronic components. More specifically, it applies to the manufacture of so-called surface-mount components, i.e. components having, on at least one side, one or more connection metallizations designed to be soldered to corresponding connection pads on an external device, such as a printed circuit board or another component.

### BACKGROUND

In some applications, there is a need for surface-mounted components in which connection metallizations designed to be soldered to an external device extend right down to the component flanks. These are known as “wettable flank” components. When the component is mounted in its environment (e.g. on a printed circuit board), the connecting metallizations (also known as electrical contacts) are soldered or brazed to corresponding metal tracks or elements on the PCB side. Some of the soldering material then rises to the sides of the components, enabling visual inspection of connection quality.

This need exists, for example, in the automotive or medical fields, and more generally in all areas where the reliability of electrical connections must be guaranteed once the circuits have been installed in their environment.

### BRIEF SUMMARY

There is a need to improve at least some aspects of known processes for manufacturing electronic components with wettable flanks.

This is achieved by a method of manufacturing electronic components with wettable flanks from a substrate, a first face of which is covered by connection terminals and in which chips are formed, the method comprising:
a first step in which a metal grid, comprising connection pads interconnected by bars, is soldered to the connection terminals,
a second step in which an insulating resin layer is formed on the substrate, the insulating resin layer surrounding the connection pads,
a third step in which the chips are separated from one another, whereby, electronic components with wettable flanks are obtained, a lateral part of the connection pads and a part of the insulating resin layer forming the flanks of the components.

According to an embodiment, in the first step, the metal grid is soldered to the connection terminals by means of a brazing layer deposited by a printing technique, preferably by screen-printed.

According to an embodiment, the screen-printed brazing layer is made of Sn or a tin alloy, such as SnAg, or SnAgCu. The screen-printed brazing layer may mechanically create an electrical connection between two or more parts.

According to an embodiment, the process comprises, prior to the second step, a step in which trenches are formed in the substrate between the chips and wherein, in the second step, the insulating resin layer fills the trenches.

According to an embodiment, after the second step, the insulating resin layer is thinned.

According to an embodiment, the method comprises the following steps:
Performing the first step,
Performing the second step,
Performing the third step.

According to an embodiment, the method comprises the following steps:
Performing the first step,
Forming trenches in the substrate,
Performing the second step,
Removing the part of the resin layer positioned both between the connection pads and above the trenches,
Carrying out the third step by thinning a second face of the substrate down to the trenches,
Applying an additional layer of resin to the second face of the substrate,
Cutting the resin into the trenches.

According to an embodiment, the method comprises the following steps:
Carrying out the first step,
Fixing the assembly obtained in the first step to a support comprising an adhesive layer by bonding the metal grid to the adhesive layer,
Carrying out the third step,
Carrying out the second step,
Cutting the resin in the trenches.

According to an embodiment, between the first step and the third step, the substrate is thinned from a second face, and in that an additional resin layer is deposited on the second face of the substrate.

This is also achieved by an electronic component with wettable flanks comprising a chip protected by a housing comprising a first main face, flanks and a second main face, connection pads being soldered to connection terminals on the chip and an insulating resin layer partially surrounding the connection pads, a lateral part of the connection pads and a part of the insulating resin layer forming the flanks of the housing.

According to an embodiment, the connection pads are soldered to the connection terminals by means of a brazing layer made of Sn or a tin alloy such as SnAg or SnAgCu, and wherein the connection pads are made of copper, possibly coated with a metallic layer. In various alternative embodiments, an electrical connection between parts may be created by soldering, sintering, US welding, laser welding, etc.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIGS. 1A, 1B and 1C show a schematic cross-section of an electronic component with wettable flanks, according to various particular embodiments;

FIG. 2A, FIG. 2B, FIG. 2C, FIG. 2D and FIG. 2E are cross-sectional views illustrating steps in a process for manufacturing an electronic component with wettable flanks according to a particular embodiment;

FIG. 3A, FIG. 3B, FIG. 3C, FIG. 3D, FIG. 3E, FIG. 3F, FIG. 3G and FIG. 3H are cross-sectional views illustrating steps in a process for manufacturing an electronic component with wettable flanks according to another particular embodiment;

FIG. 4A, FIG. 4B, FIG. 4C, FIG. 4D, FIG. 4E and FIG. 4F are cross-sectional views illustrating steps in a process for manufacturing an electronic component with wettable flanks according to another particular embodiment; and

FIG. 5 shows a variant of FIG. 4C.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

Electronic components are used in a wide range of industrial sectors, particularly in the automotive and medical fields.

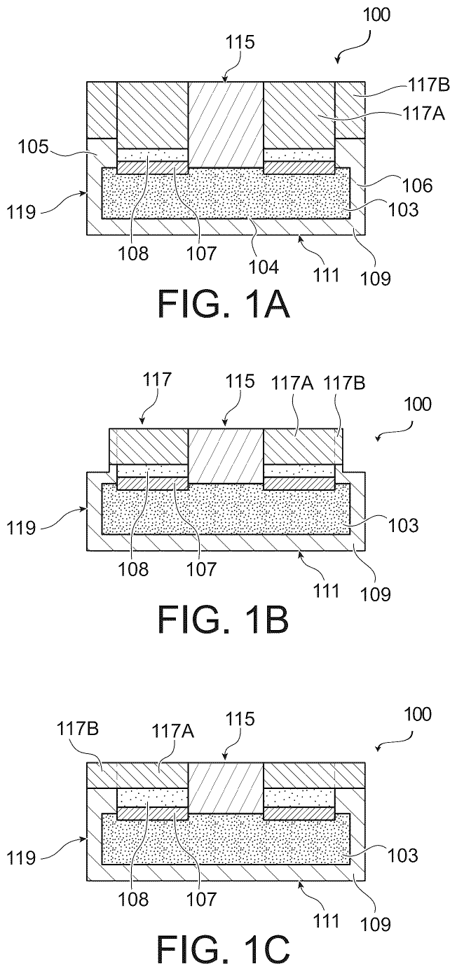

FIGS. 1A, 1B and 1C show a schematic partial cross-sectional view of electronic components 100 in different versions.

The electronic component 100 consists of an electronic chip 103 and a housing 109. In one example, the chip 103 is formed from a semiconductor substrate, such as silicon or SiC. Alternatively, the substrate can be glass or sapphire.

The chip comprises a front side 105 (also known as the first side or front face), a rear side 104 (also known as the second side or rear face) and sidewalls 106 (also known as side faces). The lower side 104 is opposite the upper side 105.

One or more connection terminals 107 (also known as electrical contacts) are formed on the top surface 105 of the microchip 103, enabling it to be connected to other elements (microchips or electronic devices).

The electrical connection terminals 107 are also called “UBM” (Under Bump Metallization). The electrical connection terminals 107 are made of a conductive material specifically designed to receive the connection studs 117, and in particular to adhere well to the studs 117. The electrical connection terminals 107 comprise at least one of the following elements: gold, titanium, nickel, copper, copper silver, tin, or tungsten. Preferably, they comprise gold or copper. Connection terminals 107 as well as stud 117 can be plated.

The electrical connection terminals 107 are, for example, 10 to 50 μm, or even 10 to 30 μm from the chip side wall. The electrical connection terminals 107 can be positioned on the top surface 105 of the chip 103 or flush with the top surface (i.e. be at the same level as the top surface 105 of the chip 103).

The chip 103 may comprise one or more discrete components. The discrete component or components are, for example, selected from transistors, diodes, thyristors, triacs, filters, etc. The chip 103 may comprise one or more electronic circuits. The chip 103 can be used to implement various electronic functions.

Component 100 is a so-called integrated component.

The chip 103 is protected by the housing 109. More specifically, the casing 109 covers at least the top surface 105. It may also cover the sides 106 of the chip 103 and/or the rear side 106 of the chip 103.

Housing 109 is at least partly made of an electrically insulating material.

In order to connect the component 100 to other electronic components and/or circuits, the housing 109 also includes connection pads 117 (also known as housing contacts or contact covers). The connection pads 117 are positioned on the top surface 105 of the chip 103. Each connection pad 117 is connected to a connection terminal 107 on the chip 103.

The connection studs 117 are made of an electrically conductive and “wettable” and/or solderable material, i.e. a material that can be soldered or otherwise mechanically attached (e.g. conductive adhesive, sintering, or welding).

The connection studs 117 are preferably made of copper, tin or one of its alloys, such as SnAgCu or SnAg, or another material with a higher melting point. The copper may be coated with an oxidation protection layer, such as a tin layer or a nickel layer, by means of Sn plating or Ni plating.

The electrical connection terminals 107 of the chip 103 and the connection studs 117 are positioned in openings in an insulating resin layer 121 covering the chip 103. The connection pads 117 comprise a first part 117A soldered to the connection terminals 107 and a second part, the so-called s 1 lateral part 117B.

The lateral part 117B of the connection studs 117 forms part of the flanks 119 of the component 100 and the first part 117A of the connection studs 117 extends over the first main face 115 of the component 100.

Component 100 is a wettable flank component, i.e. at least part of its flanks are formed by a layer of a wettable and solderable material, i.e. a material on which soldering is possible. The other part of the wettable flanks is made of an insulating resin. The layer of wettable material is formed by the lateral part 117A of the connection studs 117.

The wettable material part and the resin layer can be aligned, at the same level (FIGS. 1A, 1C) or offset from each other (FIG. 1B).

The first part 117A and the second part 117B of the connection studs 117 may be made of the same material or of different materials. These parts 117A and 117B are preferably made of the same material. Preferably, the first part 117A and the second part 117B of the connection studs 117 are made of copper.

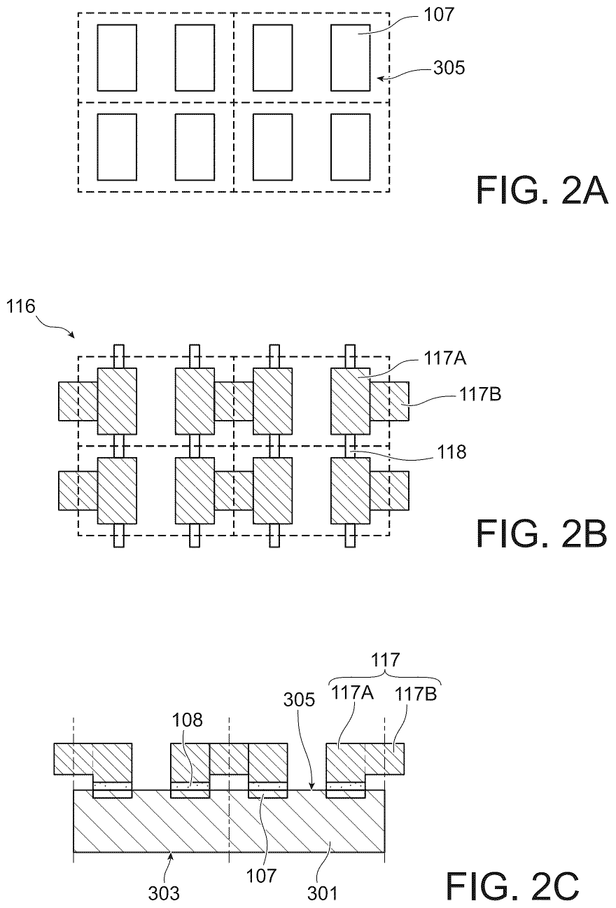

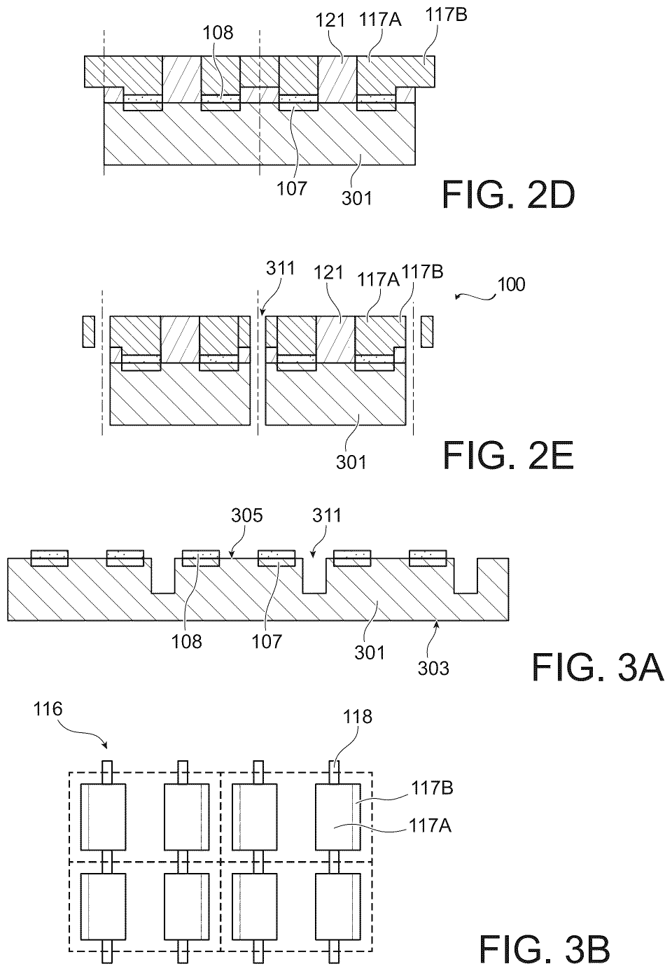

We will now describe in more detail the manufacturing process for such a component 100 with reference to FIGS. 2A to 2F, 3A to 3H and 4A to 4F.

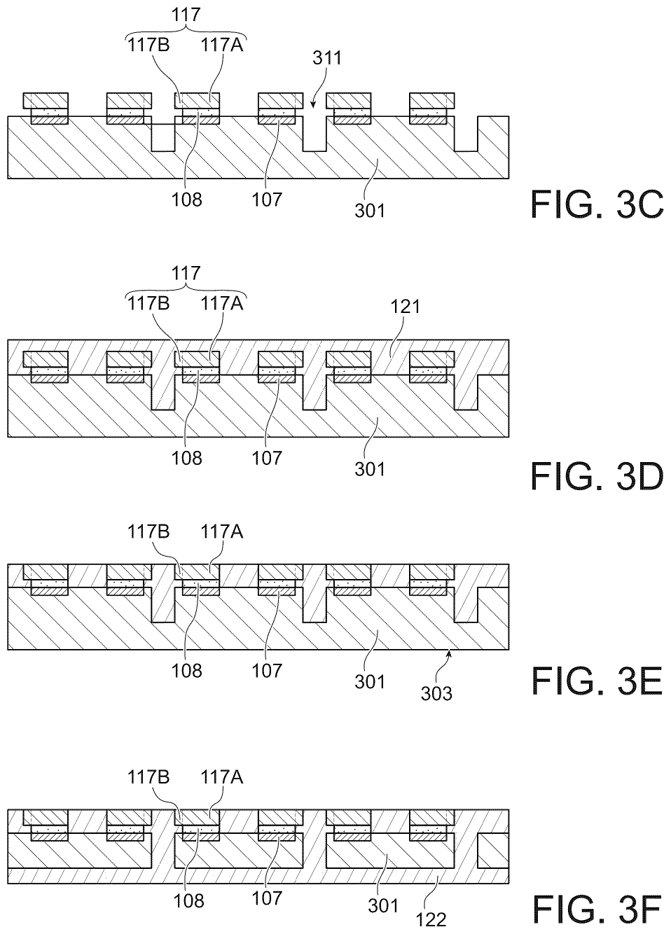

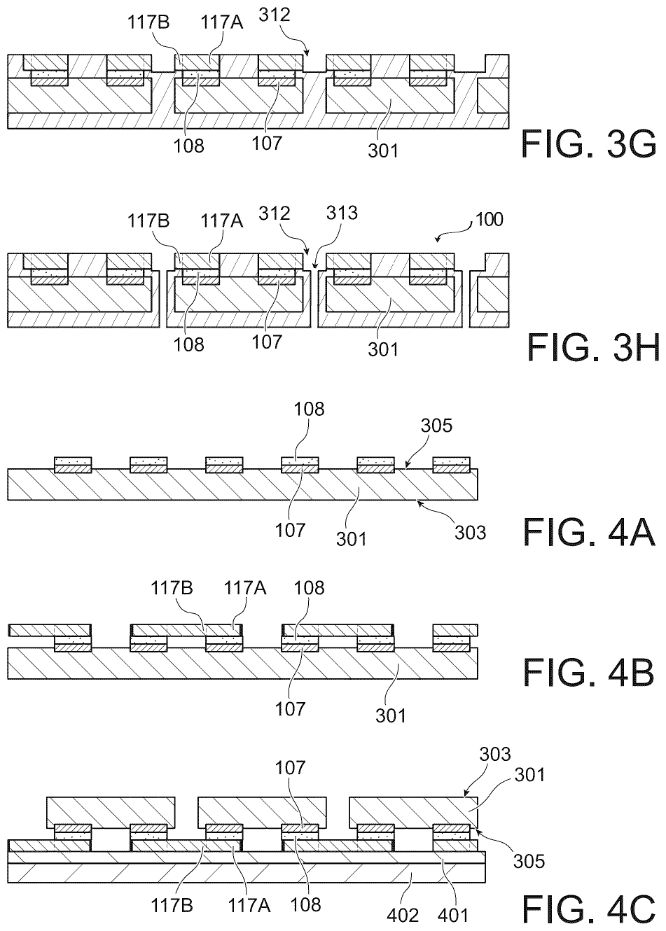

The process comprises the following steps: a) providing a substrate 301 whose first face 305 is covered by connection terminals 107 and in which chips are formed (FIGS. 2A, 3A, 4A), and providing a grid 116 (FIGS. 2B, 3B), b) soldering the grid to the connection terminals 107, using a layer 105 of solderable material (FIGS. 2C, 3C, 4B), c) depositing a layer of insulating resin 121 on the substrate 301, the layer of insulating resin 121 surrounding the connection pads 117 and filling the spaces between the various grid elements (FIGS. 2D, 3D, 4D), d) separating the chips 103 from one another (FIGS. 2E, 3F, 4C).

Steps a), b), c) and d) can be performed in the above order or in the following order: a), b), d), c).

In step a), manufacture of the discrete component(s) and/or integrated circuit(s) forming the components 100 is complete. The components 100 are formed from a single substrate 301, and have not yet been individualized. The substrate 301 comprises a first face 305 (top or front face) and a second face 303 (or back face).

Substrate 301 is, for example, a semiconductor substrate, such as silicon. It may also be SiC.

Substrate 301 has a thickness of between 300 and 900 μm, for example, a thickness of around 725 μm.

In addition, electrical connection terminals 107, described in relation to FIG. 1, have been formed on an upper face 305 of the substrate 301 (FIGS. 2A, 3A, 4A).

The grid is made up of connecting pads 117 and bars 118 connecting the individual pads 117 to each other. The bars 118 form the rows and columns of the grid 116. The pads 117 are located at the intersection of the rows and columns. The pads 117 comprise a first part 117A, which will be soldered to the connection terminals 107, and a second part 117B, which will act as a wettable material on the component sides 119.

The connection pads 117 are linked together to form a network (grid), enabling these pads 117 to be deposited on the entire substrate simultaneously. A single step is required to position all the pads 117: a significant time saving is obtained compared with positioning the pads 117 one by one.

Depending on the size of the substrate 301 and the size of the grid 116, one grid or several grids can be soldered to the same substrate 301.

In step b), the connection pads 117 are soldered to the connection terminals 107.

The brazing material is pre-deposited on the connection terminals 107. It can be deposited by a printing technique, preferably screen printing or other technique as described herein. Any additive deposition technique can be used. The brazing material can be Sn, or a tin alloy such as SnAgCu or SnAg or another alloy with a higher melting point.

In step c), an insulating resin layer 121 is deposited on the first side 305 of the substrate 301. This can be deposited by molding.

In particular, the insulating resin layer 121 is deposited on the first side 305 of the substrate 301 and in the grid spaces. In this way, the connection pads 117 are arranged within the resin. The insulating resin layer 121 forms part of the housing 109 of the components 100 and therefore protects the top face of the components 100.

The resin is an electrically insulating resin. More particularly, the resin comprises at least one base material to which electrically insulating particles are added. The base material is selected from the group comprising: epoxy-type resins, phenolic-type resins, acrylic-type resins. Preferably, the resin is an epoxy-type resin. The particles are, for example, oxide particles, in particular alumina or silica particles.

The resin is cured, for example, under ultraviolet (UV) light or by thermal activation. Annealing can be carried out after step c).

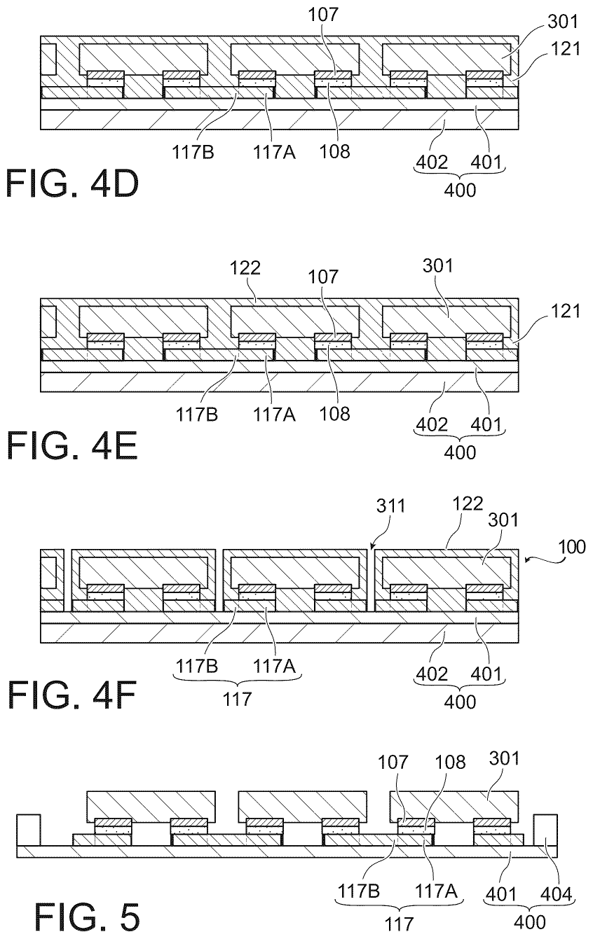

Step d) separating the chips 103 can be carried out by cutting the substrate 301 between the chips 103 (FIGS. 2E and 4C).

Alternatively, step d) can be carried out by forming trenches 311 between the chips 103 and then thinning the substrate down to the trenches 311 (FIG. 3F).

The process can be implemented in a number of different ways.

According to a first embodiment shown in FIGS. 2A to 2E, the process comprises the following steps:
implementing steps a), b) and c) described above (FIGS. 2A to 2D),
cutting the substrate 301 to separate the various components 100 (FIG. 2E).

According to this first embodiment, it is also possible to carry out one or more of the following steps:
if the resin covers the grid 116, thinning from the front side in order to remove the part of the insulating resin 121 covering the grid 116 and in particular the connection pads 117,
thinning 303 of the rear face of the substrate 301,
depositing a layer of insulating resin on the rear face of the substrate 301 to form the back of the housing 109 for the components 100 and/or on the side walls of the substrate 301.

According to a second embodiment shown in FIGS. 3A to 3H, the process comprises the following steps:
implementation of step a) (FIGS. 3A and 3B), the substrate supplied in step a) comprising trenches 311 between the chips,
implementation of step b) (FIG. 3C),
implementation of step c) (FIG. 3D),
a step of thinning the resin on the front side as it covers grid 116 (FIG. 3E),
a step of thinning the substrate 301 on the rear face and deposition of a layer of resin to cover the rear face 303 of the substrate 301 (FIG. 3E); the thinning step being advantageously carried out until the trenches 311 are reached, thus enabling the various components 100 to be easily separated at a later stage,
removal of the part of the resin positioned both above the trenches 311 and between the connection pads 117, whereby the lateral parts 117B of the connection pads 117 are separated by a gap 312 (FIG. 3G),
final cutting, forming an additional trench 313 between the components 100 (FIG. 3H).

According to a third embodiment shown in FIGS. 4A to 4F, the process comprises the following steps:
carrying out step a) (FIG. 4A),
carrying step b) (FIG. 4B),
assembling the structure obtained in step b) on a support 400 comprising an adhesive part 401 and a support substrate 402, and cutting of the substrate 301 in order to separate the various components (FIG. 4C); assembly being carried out by gluing the grid 116, and in particular the connection pads 117, to the adhesive part 401,
carrying step c) is carried out (FIG. 4D),
thinning of the resin and substrate 301 on the rear side 303 and deposition of an additional layer of insulating resin 122 on the rear side 303 of the substrate 301 (FIG. 4E),
separating the various components 100 by cutting the resin between the components 100 through the trenches 311 (FIG. 4F).

The support 400 can then be removed. For example, UV treatment or heat treatment can degrade the adhesive properties of layer 401, thereby releasing the components 100.

Advantageously, the support substrate 402 is made of glass. The adhesive layer 401 is, for example, an UV-type adhesive.

In one variant, the support comprises an adhesive layer 401 and handles 404 (FIG. 5).

In these different variants, the front-side thinning step or the rear-side thinning step can be carried out by grinding.

The thinning step 303 on the rear face produces a substrate 301 with its final thickness.

The step of forming trenches 311 can be carried out using a cutting device. The cutting device is, for example, a mechanical engraving tool such as a blade saw, or a laser engraving tool. In a preferred embodiment, the cutting device is a laser. In addition, when the cutting device is a laser, the cutting technique used can be a laser direct structuring (LDS) technique.

When singularizing, components 100 are individualized by making a cut between the components 100, for example at trenches 311. The components 100 are thus separated from each other.

The additional insulating resin layer 122 is a layer of an electrically insulating material, for example a resin of the same type as the resin layer 121. According to another example, the materials of the layers are different.

At the end of the process, the components 100 obtained are surface-mounting devices (SMDs) of the “flip-chip” type, i.e. they can be attached to an external device, such as a printed circuit board or another component, by their top face, i.e. the face on which the contacts pads 117 of the housing 109 are arranged.

To achieve this, a brazing material is positioned between the component 100 and the external device. During soldering, the soldering material rises up to the sides 119 of the 100 components, allowing verification that soldering has been carried out correctly.

Such components 100 are particularly interesting for guaranteeing the reliability of electrical connections, once the circuits have been mounted in their environment.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A method of manufacturing electronic components with wettable flanks from a substrate, a first face of which is covered by connection terminals and in which chips are formed, the method comprising:
soldering a metal grid comprising connection pads interconnected by bars to the connection terminals;
forming an insulating resin layer on the substrate, wherein the insulating resin layer surrounds the connection pads;
separating the chips from one another; and
obtaining electronic components with wettable flanks, wherein a lateral part of the connection pads and a part of the insulating resin layer form the wettable flanks of the electronic components.

2. The method of claim 1, wherein soldering the metal grid to the connection terminals is by means of a brazing layer deposited by a printing technique.

3. The method of claim 2, wherein the printing technique is for a screen-printed brazing layer made of Sn or a tin alloy.

4. The method of claim 1 further comprising:
forming, prior to forming the insulating resin layer, trenches in the substrate between the chips and wherein, in forming the insulating resin layer, the insulating resin layer fills the trenches.

5. The method of claim 1, wherein, after forming the insulating resin layer, the insulating resin layer is thinned.

6. The method of claim 1 further comprising:
forming, prior to forming an insulating resin layer, trenches in the substrate;
removing, after forming the insulating resin layer, the part of the insulating resin layer positioned both between the connection pads and above the trenches;
separating the chips from one another by thinning a second face of the substrate down to the trenches;
applying an additional layer of resin to the second face of the substrate; and
cutting the resin into the trenches.

7. The method of claim 1, wherein, between the soldering the metal grid and separating the chips, the substrate is thinned from a second face and an additional resin layer is deposited on the second face of the substrate.

8. A method of manufacturing electronic components with wettable flanks from a substrate, a first face of which is covered by connection terminals and in which chips are formed, the method comprising:
soldering a metal grid comprising connection pads interconnected by bars to the connection terminals to form an assembly;
fixing the assembly obtained by the soldering of the metal grid to a support comprising an adhesive layer by bonding the metal grid to the adhesive layer;
separating the chips from one another;
forming an insulating resin layer on the substrate, wherein the insulating resin layer surrounds the connection pads; and
cutting the resin in one or more trenches.

9. An electronic component with wettable flanks comprising a chip protected by a housing comprising:
a first main face;
a plurality of wettable flanks;
a second main face;
a plurality of connection pads soldered to connection terminals on the chip; and
an insulating resin layer partially surrounding the plurality of connection pads, a lateral part of the connection pads, and a part of the insulating resin layer forming the plurality of wettable flanks of the housing.

10. The electronic component of claim 9, wherein the connection pads are soldered to the connection terminals by means of a brazing layer of Sn or a tin alloy, and
wherein the connection pads are made of copper.
